(19) United States
(12) Patent Application Publication
(10) Pub. No.: US 2013/0026657 A1
(43) Pub. Date: Jan. 31, 2013

(54) SEMICONDUCTOR PACKAGE AND METHOD OF FABRICATING THE SAME

(71) Applicants: Wei-Chung Hsiao, Taichung (TW); Chun- Hsien Lin, Taichung (TW); Yu-Cheng Pai, Taichung (TW); Liang-Yi Hung, Taichung (TW); Ming-Chen Sun, Taichung (TW)

(72) Inventors: Wei-Chung Hsiao, Taichung (TW); Chun- Hsien Lin, Taichung (TW); Yu-Cheng Pai, Taichung (TW); Liang-Yi Hung, Taichung (TW); Ming-Chen Sun, Taichung (TW)

(73) Assignee: SILICONWARE PRECISION INDUSTRIES CO., LTD., Taichung (TW)

(21) Appl. No.: 13/243,021

(22) Filed: Sep. 23, 2011

(30) Foreign Application Priority Data
Jul. 27, 2011 (TW) 100126529

(51) Int. Cl. H01L 23/48; H01L 21/56

(52) U.S. Cl. 257/780; 438/124; 257/E21.502; 257/E23.02

(57) ABSTRACT

A semiconductor package and a method of fabricating the same. The semiconductor package includes a dielectric layer having opposite first and second surfaces; a semiconductor chip disposed on the first surface; at least two conductive pads embedded in and exposed from the first surface of the dielectric layer, and electrically connected to the semiconductor chip; a plurality of ball-implanting pads formed on the second surface of the dielectric layer; and a plurality of conductive pillars formed in the dielectric layer, each of the conductive pillars having a first end electrically connected to one of the ball-implanting pads and a second end opposing the first end and electrically connected to one of the conductive pads. Through the installation of the conductive pillars, it is not necessary for the ball-implanting pads to be associated with the conductive pads in position, and the semiconductor package thus has an adjustable ball-implanting area.

### BACKGROUND OF THE INVENTION

1. Field of the Invention

The invention is related to semiconductor packages, and, more particularly, to a semiconductor package with a flexible layout and a method of fabricating the same.

2. Description of Related Art

Along with evolution of semiconductor technology, different types of semiconductor package have been developed. In the pursuit of thinness and compactness, the quad-flat-no-lead (QFN) semiconductor package has been developed. Its defining characteristic is that leads do not protrude from the side surfaces of its encapsulant.

FIG. 1 shows a circuit structure of QFN package disclosed in U.S. Pat. No. 7,795,071, wherein an insulating layer 14 is formed on a side of openings 100 that penetrate a carrying board 10.

The insulating layer 14 has a chip-laid side 14a exposed from the openings 100 and an opposite ball-implanting side 14b. A plurality of conductive pads 12 and conductive traces 11 are embedded in the chip-laid side 14a. A plurality of ball-implanting pads 15 are embedded in the ball-implanting side 14b. The conductive traces 11 are formed among two conductive pads 12. The ball-implanting pads 15 are combined with the conductive pads 12 in the insulating layer 14. The conductive pads 12 are electrically connected to a chip (not shown). The ball-implanting pads 15 are combined with solder balls (not shown) for a circuit board (not shown) to be electrically connected thereto.

In a wiring structure according to the prior art, the positions of the ball-implanting pads 15 are aligned with those of the conductive pads 12 (central alignment), such that the positions of the solder ball layout match those of the conductive pads 12, causing both kinds of pads to be effectively locked to each other such that a ball-implanting area A′ (with a width approximately equal to 230 μm) of the ball-implanting pads 15 is thus limited and cannot be readily increased, reducing the possible bonding for the solder balls.

Additionally, a distance interval b′ between any two adjacent ball-implanting pads 15 is approximately equal to 500 μm, while the positions of the conductive pads 12 should match with those of the ball-implanting pads 15, such that the interval between any two adjacent conductive pads 12 (with a diameter d′ approximately equal to 290 μm) should also match with the interval b′ among each two adjacent ball-implanting pads 15. Since the interval between each of the adjacent conductive pads 12 cannot be increased, the number of conductive traces 11 is limited (with a line width w′ and a line interval t′ both equal to 40 μm), as illustrated in FIG. 1, making it difficult to raise the wiring density.

Thus, finding a way to overcome the wiring density bottle-neck in the prior art is an increasingly important topic.

### SUMMARY OF THE INVENTION

In view of the above-mentioned problems of the prior art, the present invention provides a semiconductor package with a flexible layout and a method of fabricating the same.

In an embodiment of the present invention, a semiconductor package includes: a dielectric layer having opposite first and second surfaces; a semiconductor chip disposed on the first surface of dielectric layer; at least two conductive pads embedded in and exposed from the first surface of the dielectric layer, and electrically connected to the semiconductor chip; a plurality of ball-implanting pads formed on the second surface of the dielectric layer; and a plurality of conductive pillars formed in the dielectric layer, each of the conductive pillars having a first end electrically connected to one of the ball-implanting pads and a second end opposing the first end and electrically connected to one of the conductive pads.

In another embodiment of the present invention, a method of fabricating a semiconductor package includes: providing a substrate; forming at least two conductive pads on the substrate; forming a plurality of conductive pillars on the at least two conductive pads; forming on the substrate a dielectric layer that covers the conductive pillars and conductive pads and leaves the conductive pillars exposed; forming on the dielectric layer and the conductive pillars a plurality of ball-implanting pads electrically connected to the conductive pads; forming on the dielectric layer an insulating protection layer that leaves the ball-implanting pads exposed; penetrating the substrate to form openings, from which the conductive pads are exposed; and disposing in one of the openings a semiconductor chip electrically connected to the conductive pads.

In yet another embodiment of the present invention, the conductive pillars are formed on the conductive pads first, and then the ball-implanting pads are formed on the conductive pillars, such that the ball-implanting pads and the conductive pads have no need to be aligned with one another in position. Therefore, the ball-implanting pads and the ball-implanting area may be disposed at will, and the solder ball arrangement may have an adjustable layout.

Moreover, since the conductive pads have no need to associate with the ball-implanting pads in intervals, the interval between any two adjacent conductive pads can be adjusted on demand. Therefore, any reasonable number of conductive traces may be formed between any two adjacent conductive pads.

### BRIEF DESCRIPTION OF DRAWINGS

FIG. 1 is a cross-sectional view of a QFN package according to the prior art; and

FIGS. 2A-2G are cross-sectional views illustrating a method of fabricating a semiconductor package according to the present invention, wherein FIGS. 2E′ and 2F′ are other embodiments of FIGS. 2E and 2F.

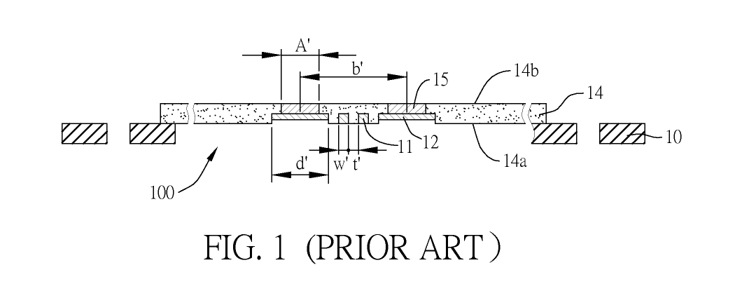

### DETAILED DESCRIPTION OF PREFERRED EMBODIMENTS

The following is an explanation of the disclosed embodiments, such those familiar with this technical field can easily understand the advantages and efficacy.

Note that the illustrated structure, ratio and size of the appended figures in the explanation are only provided for general understanding, not intended as specific limitations. As such, they are not applicable for limiting the implementations of the disclosed embodiments. Modification of structure, change of ratio and adjustment of size will fall within the scope of the disclosed embodiments when the general technical essence of the disclosed embodiments is not affected. Meanwhile, terms in the explanation like “upper,” “a,” and so on are only provided for convenience of description rather than limiting the feasible scope of the disclosed embodiments. Change or adjustment of such relative relationships without meaningful alteration of the techniques involved should be viewed as within the feasible scope of the disclosed embodiments.

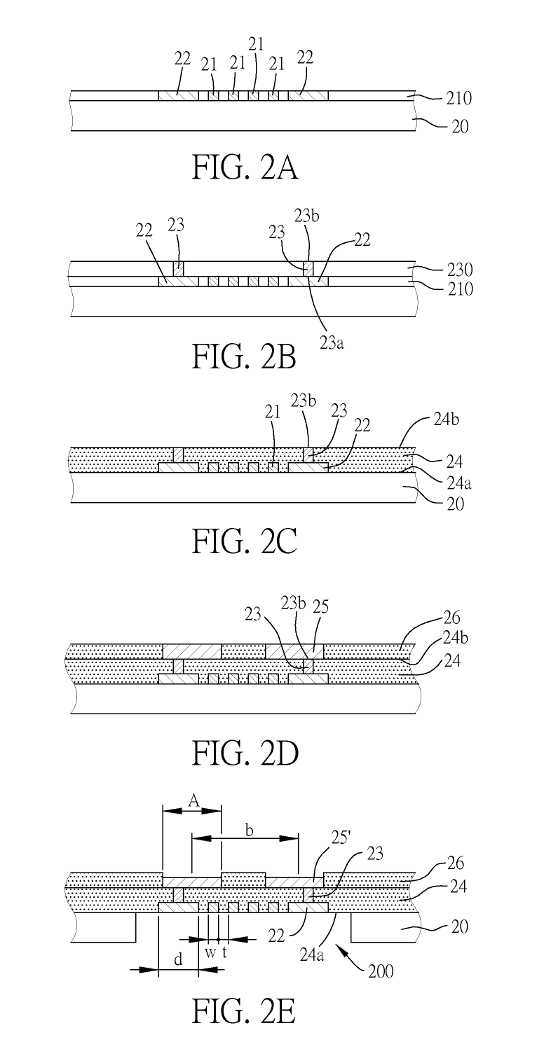

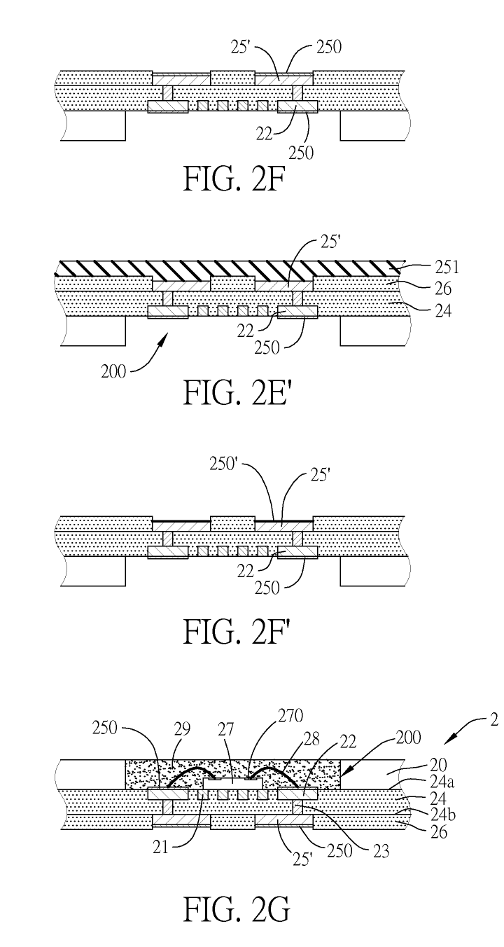

FIGS. 2A-2G are cross-sectional views illustrating a method of fabricating a semiconductor package 2 according to the present invention.

As shown in FIG. 2A, a substrate 20 is provided and processed by a pattern etching process, in which a photoresist layer 210 is formed on the substrate 20, and a portion of the substrate 20 that is not covered by the photoresist layer 210 is electroplated to form a plurality of conductive traces 21 and at least two conductive pads 22, the conductive traces 21 being formed between the at least two conductive pads 22.

As shown in FIG. 2B, another pattern etching process is performed to form a conductive pillar 23 on each of the conductive pads 22 by another photoresist layer 230, wherein the conductive pillar 23 has a first end 23a and an opposite second end 23b. The first end 23a is in physical and electrical contact with the conductive pad 22.

As shown in FIG. 2C, the photoresist layers 210 and 230 are removed, and a dielectric layer 24 having opposing first and second surfaces 24a, 24b is formed on the substrate 20 to cover the conductive traces 21, the conductive pads 22 and at least portions of the conductive pillars 23. In an embodiment, the first surface 24a of the dielectric layer 24 contacts the substrate 20, and the second surface 24b of the dielectric layer 24 exposes the second ends 23b of the conductive pillars 23.

As shown in FIG. 2D, a pattern etching process is performed by a photoresist layer (not shown) to form a plurality of ball-implanting pads 25 on the second surface 24b of the dielectric layer 24 and the second end 23b of the conductive pillars to electrically connect the conductive pillars 23, wherein the photoresist layer is removed after formation. Then, an insulating protection layer 26 is formed on the second surface 24b of the dielectric layer 24 and ground with the ball-implanting pads 25 by a grinding process, such that the ball-implanting pads 25 are exposed from the insulating protection layer 26.

In an embodiment, the insulating protection layer 26 and the dielectric layer 24 are made of the same material, such as a molding compound. However, the insulating protection layer 26 and the dielectric layer 24 may be made of different materials in other embodiments.

As shown in FIG. 2E, the substrate 20 is penetrated by an etching process to form openings 200, with the electric contact pads 22 and a part of the first surface 24a of the dielectric layer 24 exposed from the openings 200.

In the etching process, the ball-implanting pads 25′ are slightly recessed with the exposed surface of the ball-implanting pads 25′ lower than the exposed surface of the insulating protection layer 26. However, no specific limitation on the height of the ball-implanting pads is intended, and, in other embodiments, the exposed surfaces of the insulating protection layer 26 and ball-implanting pads 25 are coplanar.

As shown in FIG. 2F, a surface treatment layer 250 is formed on the conductive pads 22 and the ball-implanting pads 25′ by a pre-plated lead frame technique. In an embodiment, the surface treatment layer 250 is made of Ni/Pd/Au.

As shown in FIGS. 2E′ and 2F′, a metal layer 251 is first formed on the insulating protection layer 26 and the ball-implanting pads 25′ by an electroless plating process, and the openings 200 are formed; and then the surface treatment layer 250 is formed on the conductive pads 22 and the metal layer 251 is removed. Then, another surface treatment layer 250′ is formed on the ball-implanting pads 25′. In an embodiment, said another surface treatment layer 250′ is made of an organic solderability protective (OSP) material.

As shown in FIG. 2G (which is oriented upside down with respect to the other figures), subsequent to the process shown in FIG. 2F, a semiconductor chip 27 is disposed on the first surface 24a of the dielectric layer 24 in one of the openings 200, and conductive pads 270 of the semiconductor chip 27 are electrically connected to the conductive pads 22 by bonding wires 28 by a wire-bonding process.

Then, an encapsulant 29 is formed on the first surface 24a of the dielectric layer 24 in the openings 200 to encapsulate the semiconductor chip 27, the bonding wires 28, the conductive pads 22 and the surface treatment layer 250.

In an embodiment, conductive elements (not shown) such as solder balls may be disposed on the ball-implanting pads 25′ (or on the surface treatment layer 250, 250′) to combine with an electronic device (not shown), such as a circuit board.

In the method of fabricating a semiconductor package according to the present invention, conductive pillars 23 are first formed on the conductive pads 22, and then the ball-implanting pads 25′ are formed on the conductive pillars 23, such that the position and ball-implanting area A of the ball-implanting pads 25′ can be adjusted on demand. Therefore, the solder balls may have a flexible layout, as shown in FIG. 2E. Compared to the prior art, the ball-implanting pads 25′ may have an increased ball-implanting area A (with a width approximately equal to 350 μm) that is not limited by the position of the conductive pads 22. Therefore, the solder balls can be securely combined with the ball-implanting pads and the semiconductor package can have improved reliability.

Through the connection of the conductive pillars 23 to the conductive pads 22 and the ball-implanting pads 25′, the interval between any two adjacent conductive pads 22 need not be associated with the ball-implanting interval b between any two adjacent ball-implanting pads 25. Therefore, the interval and diameter of the conductive pads 22 may be adjusted on demand, and the conductive pads 22 may have a flexible layout. Thus, as the ball-implanting interval b is approximately equal to 500 μm, the conductive pillars 23 may be displaced relative to the center of the ball-implanting pads 25′, and the conductive pads 22 (with a diameter d approximately equal to 220 μm) may have their intervals increased. Compared to the prior art, a semiconductor package according to the present invention may have any reasonable number of conductive traces 21 formed between any two adjacent conductive pads 22. For example, four conductive traces 21 (with a line width w and a line interval t both approximately equal to 40 μm) may be formed between the at least two conductive pads 22, thus increasing the layout density.

The present invention also provides a semiconductor package 2, including: a dielectric layer 24 having a first surface 24a and an opposite second surface 24b, a semiconductor chip 27 disposed on the first surface 24a of the dielectric layer 24, at least two conductive pads 22 embedded in the first surface 24a of the dielectric layer 24 and electrically connected to the semiconductor chip 27, a plurality of ball-implanting pads 25 and 25′ formed on the second surface 24b of the dielectric layer 24 and embedded in the first surface 24a of the dielectric layer 24, a plurality of conductive traces 21 located between the at least two conductive pads 22, and a plurality of conductive pillars 23 formed in the dielectric layer 24.

The conductive pads 22 are exposed from the first surface 24a of the dielectric layer 24 and are electrically connected to conductive pads 270 of the semiconductor chip 27 by bonding wires 28.

The conductive pillars 23 have first ends 23a electrically connected to the conductive pads 22, and second ends 23b opposing the first ends 23a and electrically connected to the ball-implanting pads 25, 25′ and the conductive pads 22.

In an embodiment, the semiconductor package 2 further includes an encapsulant 29 formed on the first surface 24a of the dielectric layer 24 to encapsulate the semiconductor chip 27, the bonding wires 28 and the conductive pads 22. In another embodiment, the semiconductor package 2 further comprises an insulating protection layer 26 formed on the second surface 24b of the dielectric layer 24 for the ball-implanting pads 25, 25′ to be exposed therefrom.

In an embodiment, the semiconductor package 2 further includes a surface treatment layer 250 formed on the conductive pads 22, and the surface treatment layer 250 is made of Ni/Pd/Au. In another embodiment, the semiconductor package 2 further comprises surface treatment layers 250, 250′ on the ball-implanting pads 25, 25′, and the surface treatment layer 250, 250′ are made of Ni/Pd/Au or an organic solderability protective material. In an embodiment, the semiconductor package 2 further includes a substrate 20 having openings 200 penetrating therethrough, and the first surface 24a of the dielectric layer 24 is disposed on the substrate 20 to cover one end of each of the openings 200 to make the semiconductor chip 27 and the conductive pads 22 all to be disposed in the openings 200.

In conclusion, a semiconductor package and a method of fabricating the same in an embodiment according to the present invention connect conductive pads and ball-implanting pad by two ends of conductive pillars, such that there is no need to inflexibly associate the solder balls with the conductive pads in position, and the position of the ball-implanting pads, the ball-implanting area, the interval between any two adjacent conductive pads, and the number of conductive traces can be adjusted on demand to achieve the purpose of flexible trace routing.

The above-mentioned exemplary embodiments illustratively explain the theory and efficacy of the invention, rather than limit the invention to the exact features of the embodiments. Those familiar with this technical field will be able to make various changes to the embodiments and practice of the invention without altering the spirit and scope of the invention as disclosed in the following claims.

What is claimed is:

1. A semiconductor package, comprising:
a dielectric layer having a first surface and a second surface opposing the first surface;
a semiconductor chip disposed on the first surface of the dielectric layer;
at least two conductive pads embedded in and exposed from the first surface of the dielectric layer, and electrically connected to the semiconductor chip;
a plurality of ball-implanting pads formed on the second surface of the dielectric layer; and
a plurality of conductive pillars formed in the dielectric layer, each of the conductive pillars having a first end electrically connected to one of the ball-implanting pads and a second end opposing the first end and electrically connected to one of the conductive pads.

2. The semiconductor package of claim 1, further comprising a plurality of bonding wires electrically connected the semiconductor chip to the conductive pads.

3. The semiconductor package of claim 1, further comprising a surface treatment layer formed on the conductive pads.

4. The semiconductor package of claim 3, wherein the surface treatment layer is made of Ni/Pd/Au.

5. The semiconductor package of claim 1, further comprising a surface treatment layer formed on the ball-implanting pads.

6. The semiconductor package of claim 5, wherein the surface treatment layer is made of Ni/Pd/Au or an organic solderability protective material.

7. The semiconductor package of claim 1, further comprising an encapsulant formed on the first surface of the dielectric layer and covering the semiconductor chip and the conductive pads.

8. The semiconductor package of claim 1, further comprising a substrate having openings penetrating therethrough, wherein the first surface of dielectric layer is formed on the substrate to seal one end of each of the openings.

9. The semiconductor package of claim 8, wherein the semiconductor chip is disposed in one of the openings, and the conductive pads are exposed from the openings.

10. The semiconductor package of claim 1, further comprising an insulating protection layer formed on the second surface of the dielectric layer, wherein the ball-implanting pads are exposed from the insulating protection layer.

11. The semiconductor package of claim 1, further comprising a plurality of conductive traces embedded in the first surface of the dielectric layer and formed between the at least two conductive pads.

12. A method of fabricating a semiconductor package, comprising:
providing a substrate;
forming at least two conductive pads on the substrate;
forming a plurality of conductive pillars on the at least two conductive pads;
forming on the substrate a dielectric layer that covers the conductive pillars and the conductive pads and leaves the conductive pillars exposed;
forming on the dielectric layer and the conductive pillars a plurality of ball-implanting pads electrically connected to the conductive pads;
forming on the dielectric layer an insulating protection layer that leaves the ball-implanting pads exposed;
penetrating the substrate to form openings, from which the conductive pads are exposed; and
disposing in one of the openings a semiconductor chip electrically connected to the conductive pads.

13. The method of claim 12, wherein at lease one of the conductive pads, the conductive pillars and the ball-implanting pads is formed by an electroplating process.

14. The method of claim 12, wherein the openings are formed by an etching process.

15. The method of claim 12, wherein the semiconductor chip is electrically connected to the conductive pads by a wire-bonding process.

16. The method of claim 12, further comprising forming a surface treatment layer on the conductive pads and the ball-implanting pads after the openings are formed.

17. The method of claim 16, wherein the surface treatment layer is made of Ni/Pd/Au.

18. The method of claim 12, further comprising forming a metal layer on the insulating protection layer and the ball-implanting pads before the openings are formed, forming a surface treatment layer on the conductive pads after the openings are formed, and removing the metal layer.

19. The method of claim 18, wherein the metal layer is made of copper by an electroless plating process.

20. The method of claim 18, further comprising forming another surface treatment layer on the ball-implanting pads after the metal later is removed.

21. The method of claim 20, wherein the another surface treatment layer is made of Ni/Pd/Au or an organic solderability protective material.

22. The method of claim 12, further comprising filling the openings with an encapsulant that covers the semiconductor chip and the conductive pads.

23. The method of claim 12, further comprising forming on the substrate a plurality of conductive traces that are formed between the at least two conductive pads.

24. The method of claim 23, wherein the conductive traces are formed by an electroplating process.
